(19) United States
(12) Patent Application Publication
(10) Pub. No.: US 2008/0278894 A1
(43) Pub. Date: Nov. 13, 2008

(54) DOCKING STATION FOR PROJECTION DISPLAY APPLICATIONS

(75) Inventors: Dongmin Chen, Saratoga, CA (US); Michael Aaron Thompson, Mountain View, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Miradia Inc., Sunnyvale, CA (US)

(21) Appl. No.: 11/747,864

(22) Filed: May 11, 2007

(51) Int. Cl. H05K 5/00; H02J 7/00

(52) U.S. Cl. 361/681; 320/137

(57) ABSTRACT

A projection docking station includes a docking port configured to communicate with a portable device and a projection unit configured to perform a projection process for an image. The projection docking station also includes a communication interface configured to provide communications between the docking port and the projection unit and a control unit configured to communicate with the communication interface and the projection unit. The control unit is configured to control a communication flow between the communication interface and the docking port, a communication flow between the communication interface and the projection unit, and the projection process.

### BACKGROUND OF THE INVENTION

The present invention relates generally to a projection docking station for display applications. More particularly, embodiments of the present invention provide methods and systems for projecting images stored in or transmitted through a portable electronic device. In a specific embodiment, a mobile phone is positioned in the projection docking station during presentation of a multimedia document stored in a mobile phone. The invention is applicable to other devices including mobile computers, personal digital assistants, gaming device, and the like.

With the increasing development and convergence of semiconductor technology and communications technology, the capacity of portable devices or mobile devices such as cell phones, game players, and personal digital assistants (PDAs) to store and process information is increasing. For example, a mobile phone is now far more than merely a tool for making a phone call. It can be used to surf the Internet, play games, and watch films, among other applications. In order to display more text, graphics, and/or video information that is stored on or transmitted through these portable devices, there is a need to increase the screen size of the portable devices. For portable devices, however, small size and compactness are design goals that run counter to increased screen size. Due to the small physical size of portable devices as appropriate for portable applications, the capacity for expansion of the screen size is limited.

One possible approach for alleviating these display problems is a higher level of resolution. Unfortunately, a small screen, even with a high resolution, may result in viewer fatigue. Small screens may also be inconvenient if several users want to view the information displayed on the screen at the same time.

Therefore, there is a need in the art for methods and systems for displaying information stored in or transmitted through portable electronic devices.

### SUMMARY OF THE INVENTION

According to an embodiment of the present invention, a projection docking station is provided. The projection docking station includes a docking port configured to communicate with a portable device and a projection unit configured to perform a projection process for an image. The projection docking station also includes a communication interface configured to provide communications between the docking port and the projection unit and a control unit configured to communicate with the communication interface and the projection unit. The control unit is configured to control a communication flow between the communication interface and the docking port, a communication flow between the communication interface and the projection unit, and the projection process.

According to another embodiment of the present invention, a method of operating a projection docking station is provided. The method includes coupling a portable device to a docking port of the projection docking station and determining if a projection process is to be performed using the docking station. The method also includes transmitting data from the portable device to a communication interface of the docking station and projecting an image from a projection unit of the docking station.

According to a specific embodiment of the present invention, a method of operating a projection docking station is provided. The method includes coupling a portable device to a docking port of the docking station and determining that a charging process is to be performed on the portable device. The method also includes determining a power source to be used for the charging process and charging the portable device using power from the power source.

Numerous benefits are achieved using the present invention over conventional techniques. For example, in an embodiment according to the present invention, one or more users may conveniently and comfortably view information provided using a portable device. The information, which may be multimedia, is projected in embodiments using a docking station that may be carried by a user along with the portable device. Thus, embodiments provide a form factor for the docking station that is more portable than a conventional projector. The image to be displayed from the portable device may be projected onto a screen or a wall of greater size through the docking station, making it convenient for the one or more users to view the image, especially in the context of multiple users. Moreover, embodiments include a power management unit that enables the portable device to operate with improved power efficiency. Depending upon the embodiment, one or more of these benefits may exist. These and other benefits have been described throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIGS. 1A and 1B are perspective views of a projection docking station according to an embodiment of the invention;

FIG. 2 is a simplified block diagram of the projection docking station illustrated in FIGS. 1A and 1B;

FIG. 3 is a simplified block diagram of the communication interface illustrated in FIG. 2;

FIG. 4 is a simplified flowchart illustrating operation of the docking station in a projection application according to an embodiment of the present invention; and

FIG. 5 is a simplified flowchart illustrating operation of the docking station in a charging application according to an embodiment of the present invention.

### DETAILED DESCRIPTION OF SPECIFIC EMBODIMENTS

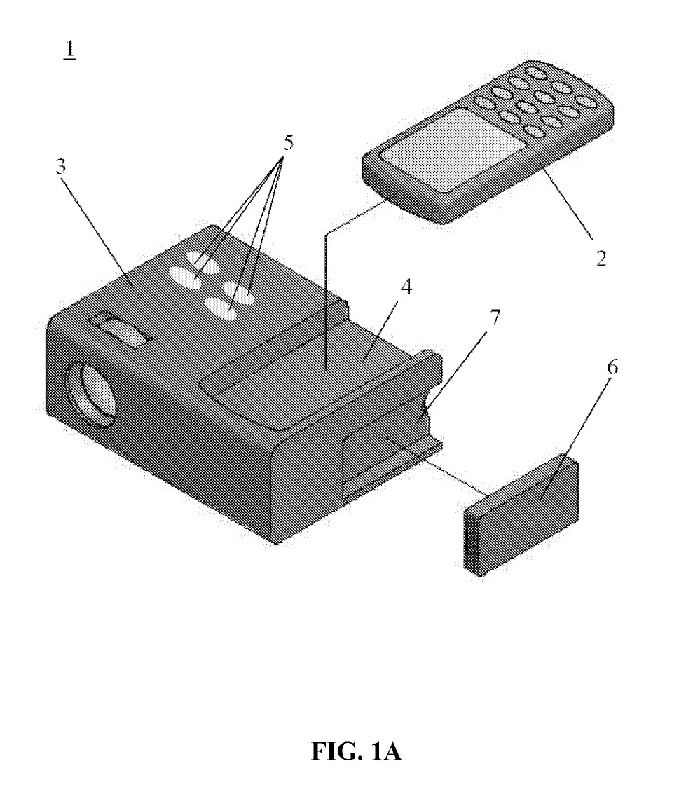

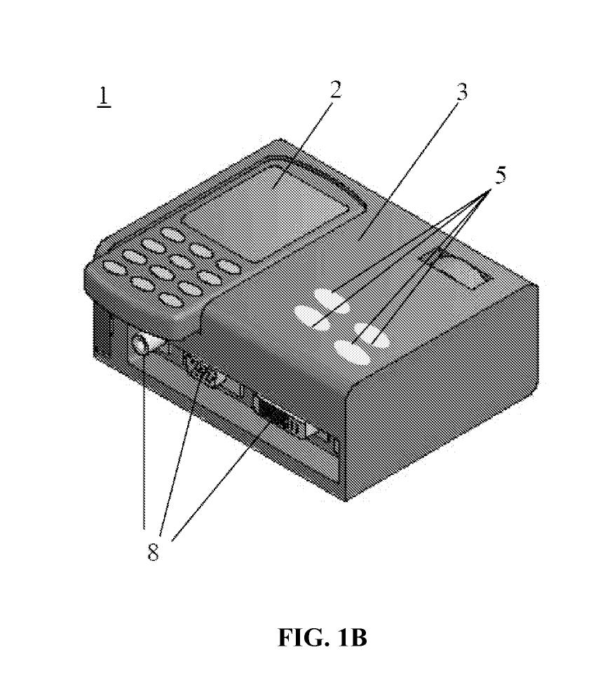

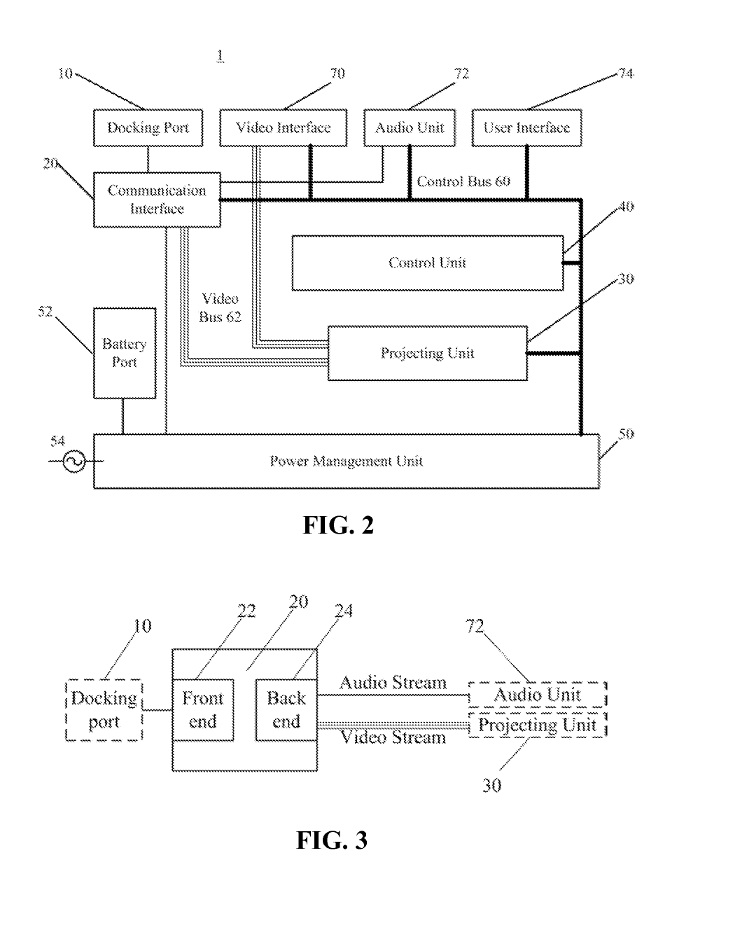

FIG. 1A illustrates a projection docking station 1 according to an embodiment of the present invention. FIG. 1B illustrates docking station 1 with a portable device 2 docked therein. The docking station 1 shown in FIGS. 1A and 1B includes a housing 3 for accommodating therein the components of the docking station, which will be described in additional detail with reference to FIG. 2. A projection unit (not shown in FIGS. 1A and 1B) is installed in the housing 3 and has its projection lens exposed through the front side surface of the housing 3 for projecting an image onto a screen, a wall, and the like. The term “image” as used herein refers to any visual information, for example, including not limited to a video image such as a moving image/frame and a still picture, but also a text image. Additionally, embodiments of the present invention provide for production of audio information, thereby providing for the display of multimedia information to one or more viewers.

As shown in FIGS. 1A and 1B, a docking bay 4 is provided on an upper surface of the housing 3 for receiving a portable device 2 and a battery bay 7 is provided on a side surface of the housing 3 for receiving a battery 6. Although the docking bay 4 and the battery bay are illustrated on the upper and side surfaces of the housing 3 in FIGS. 1A and 1B, the placement of these elements in these particular positions are not required by the present invention. Moreover, the expression “on the surface of the housing” is to be understood to refer to embodiments in which the docking bay or the battery bay are formed on the surface, in the surface, or inside the housing with an opening to the surface. The term “docking” as used herein is to be understood to mean that a first object may be placed at or in a second object in a manner suitable for one or more signals, data, and/or power communication between the first object and the second object. Furthermore, the term “docking” is also to be understood to refer to connecting the first object (e.g., a mobile device) to the second object (e.g., a docking bay) via a cable as an auxiliary docking connector.

Referring to FIGS. 1A and 1B, the housing 3 also includes a set of connectors 8. The connectors 8 include, for example, an audio port, an A/C power connector, and a flash memory port as well as DVI, RCA, HDMI, and/or other suitable cable connectors for connecting to other video and/or audio sources. There are also several control buttons 5 provided on the housing 3 for operating the docking station 1. These control buttons may include buttons or switches for power on/off, focus adjustment, menu item navigation, input selection, and the like. Some of these control buttons may share functionality with functionality provided on other types of projectors.

It will be readily understood that it is not necessary to position the docking bay 4 and the battery bay 7 on any specific surface. FIGS. 1A and 1B are only illustrative. Any positions where the docking bay 4 and the battery bay 7 may be accessible are also possible. Moreover, the housing 3 is not limited to the parallelepiped profile as shown, and other shapes may be utilized. One of ordinary skill in the art would recognize many variations, modifications, and alternatives.

In the embodiment illustrated in FIGS. 1A and 1B, the docking bay 4 is configured to receive therein a portable device 2 such as a cell phone, a mobile PC, a game player, a PDA, or another suitable device. In fact, the portable device 2 may also be a still camera, a video camera or memory cards including xD, SD, Compact Flash (CF), flash drive, and the like. Hereinafter, a cell phone will be taken as an example for the portable device 2.

FIG. 2 is a simplified block diagram of the projection docking station illustrated in FIGS. 1A and 1B. The docking station 1 may include a docking port 10, a communication interface 20, a projection unit 30 and a control unit 40. Optionally, the docking station 1 may further include a power management unit (PMU) 50, a video interface 70, an audio unit 72, and a user interface 74. The PMU 50 may be coupled to a battery port 52 and an electric outlet 54. The docking station 1 may further include a control bus and a video bus for communication between components. Additional description related to these components of the docking station 1 are provided throughout the present specification.

The communication between the communication interface 20 and the projection unit 30 may include transmission of image data from the communication interface 20 to the projection unit 30. The communication between the communication interface 20 and the docking port 10 may include transmission of video and audio data from the docking port 10 to the communication interface 20. The communication between the communication interface 20 and the docking port 10 may additionally include power transmission from the communication interface 20 to the docking port 10. In addition, the communication between the components may include necessary control signals. The communications between the above components are also described in additional detail throughout the present specification.

The docking port 10 is adapted to communicate with the cell phone 2. The docking port 10 may receive, for example, video and audio data from the cell phone 2. The docking port 10 may also function as a path through which the cell phone 2 is supplied with power and/or charged. The docking port 10 may be designed corresponding to the input/output port of the cell phone 2. In accordance with various protocols, the communication between the docking port 10 and the cell phone 2 may be implemented by means of electrical contacts or terminals, or in the form of wireless communication such as infrared, Bluetooth, or radio frequency communication. In the case of wireless communication, the docking port 10 may include a wireless transceiver (not shown) for wirelessly communicating with the cell phone 2. The docking port 10 is in turn connected to the communication interface 20, via, for example, a number of terminals.

In some embodiments, the docking port 10 may be provided in the docking bay 4 in the form of electrical contacts. However, in the case where wireless communication is utilized, the docking bay 4 may not be utilized or may still be shaped to receive the cell phone 2 therein. A user may hold the cell phone 2 while wireless or wired communication is performed between the cell phone 2 and the docking port 10.

Referring to FIG. 2, a communication interface 20 is connected to the docking port 10. FIG. 3 is a simplified block diagram of the communication interface illustrated in FIG. 2. The communication interface 20 may include a front end 22 and a back end 24. The front end 22 of the communication interface 20 communicates with the docking port 10 to receive signals from or send signals to the docking port 10. The front end 22 of the communication interface 20 may contain a plurality of I/O terminals corresponding to the plurality of terminals in the docking port 10, for receiving external signals such as video, audio and text data signals and/or control signals from the cell phone 2. The received signals may experience voltage level translation, since the front end 22 of the communication interface 20 to different mobile devices may be based on different I/O voltage levels.

The back end 24 of the communication interface 20 provides video streams to the projection unit 30, and may also provide audio streams to the optional audio unit 72 if appropriate. The video and audio streams may be provided upon receiving a request from the control unit 40, or provided automatically when a determination is made that a mobile device is connected to the docking port 10 in a wired or wireless manner. The back end 24 of the communication interface 20 may contain a sub-frame buffer providing synchronization between clock domains. The communication interface 20 may also provide a method for aligning the audio and video streams, for example, at the back end.

In the communication interface 20, a method of ensuring data integrity may be implemented at the data link layer. For example, handshaking may be implemented to ensure delivery, checksums may be implemented to detect transmission errors, especially for control communication, and error correction can be done algorithmically or by retransmission depending on the device's protocol capabilities.

The projection unit 30 is responsible for taking an input video stream from the communications interface 20 and producing a high quality projected image. The projection unit 30 may translate an input video stream into a “planarized” format that is appropriate for microdisplay temporal modulation. The projection unit 30 may include microdisplay devices such as MEMS or LCOS (liquid crystal on silicon), HTPS (high temperature polysilicon), and the like. Various illumination sources including LED, ultra-high-pressure (UHP) arc lamp, laser, or other sources are utilized in embodiments of the present invention. The projection unit 30 may also contain a variety of other components and peripherals such as color wheels, power monitors, configuration EEPROMs, D/A converters, and temperature monitors. Also, the projection unit 30 may be implemented in structure as any conventional projector, and detailed description of its structure will be omitted for purposes of clarity.

In the projection unit 30, various projection-related processes may be performed in various ways by a controller therein comprising a microprocessor or dedicated IC, RAM, ROM, or the like. For example, Gamma correction may be accomplished via reconfigurable content addressable Look Up Tables (LUTs). The planarized frames may be double buffered in RAM. A Display Control Engine (DCE) may implement a micro-code engine for fetching buffered sub-frames and mastering micro-display modulation. The modulation sequence may be stored in local RAM for user flexibility and customization. Other video processing may also be supported by the projection unit 30 for such functions as video decompression, a digital signal processor (DSP) for image quality and enhancement, scaling, and video overlays.

The projection unit 30 may scale the resolution of input video stream for the projection display. Buffers may be implemented to facilitate scaling. The video resolution may be scaled up or down to the full resolution of the projection unit 30 or a smaller resolution as appropriate to the particular application. One of ordinary skill in the art would recognize many variations, modifications, and alternatives.

The control unit 40 provides overall control for the docking station 1 and may include a commercially available programmable microprocessor, a dedicated microprocessor, or custom developed logic. Some of the control may be based on input from a user via the control buttons 5 mentioned above. Referring again to FIG. 2, the control unit 40 communicates with the communication interface 20, the projection unit 30 and the audio unit 72, by sending various commands and receiving various responses. For example, the control unit 40 may output a docking command towards the communication interface 20 to allow the communication interface 20 to receive video and audio data from the cell phone 2 via the docking port 10.

In addition, the control unit 40 may adjust the performance of the docking station 1 in accordance with the configuration, such as system parameters, e.g. microdisplay voltages, timing, power mitigation parameters, and sensor configuration via configuration registers, etc. and programmable modulation microcode sequences. The control unit 40 may also perform the event handling of the cell phone 2. Such events include, but are not limited to, an incoming phone call, SMS, MMS, email, alarm, and the like. The handling for an event such as an incoming phone call may be, for example, to freeze the present display of the cell phone 2 or of the projection unit 30, switch to a phone mode, enable the speakerphone, and play a piece of audio for event notifications. The control unit 40 may also provide other functions, for example, a development interface, host interface, firmware upgrade, and/or a control bus master.

According to an embodiment of the present invention, the image to be displayed from the cell phone 2 may be projected onto a screen or a wall of greater size through the docking station 1. The docking station 1 possesses more portability than a conventional externally connected projector, while still providing a form factor suitable for incorporating a projection unit therein. Therefore, it is very convenient for one or more users to view the multimedia information projected from the docking station, especially in situations in which a number of people want to or need to concurrently view the multimedia information.

In addition to the previously described elements, docking stations provided by embodiments of the present invention may include additional components. It should be noted that these components are only optional and may be absent in the docking station 1 or be replaced with other means though their presence provides the docking station 1 with more advantages.

Referring to FIG. 2, control bus 60 may be provided for communication of control signals between all of the components in the docking station 1. The control bus 60 may be a shared medium with multiple masters and slaves, and implement functionality for arbitration and contention resolution. Arbitration may be centralized in the control unit 40 or distributed as in standard 2-wire serial buses like I²C or System Management Bus (SMBus). In the absence of the control bus 60, the above components in the docking station 1 may separately communicate with each other.

The video bus 62 may be provided as a video data path to the projection unit 30 from the communication interface 20 and the optional video interface 70. The video bus 62 may use an internal standard for transferring video data and embedded control. The video bus 62 may also target a particular video format depending on customer requirements. The video bus 62 may provide a handshaking interface mastered by the projection unit 30 as a means of applying backpressure and for crossing clock domains. In the invention, a format of component video with 8 bits of data for each color Red, Green, and Blue along with horizontal and vertical video synchronization signals, for example, may be used, while other data formats are also possible.

The video interface 70 may be provided for connecting other external video sources, such as a computer or a DVD player, to the docking station 1 for display by the projection unit 30. The video interface 70 may provide a buffer for the incoming video and audio which acts to cross clock domains to the projection unit 30, and can convert the video to the internal standard. As shown in FIG. 1B, the docking station 1 may include a set of connectors 8 forming a part of the video interface 70.

The audio unit 72 may be provided for driving speakers in the docking station 1 with the audio stream from the communication interface 20. The audio unit 72 may provide amplification and volume control as well as audio format detection, decompression and other processing functions, and may optionally drive audio outputs for an external sound system. It will also be readily understood that the audio unit 72 is not always necessary, for example in the case where the speaker of the cell phone 2 itself is satisfactory.

The optional external user interface 74 may be provided to connect with the control unit 40, for example, via the control bus 60. The user interface 74 is used for a user to input various commands to and get various desired information from the docking station 1, and may be implemented by any appropriate input device such as a keypad and buttons, and provided with any display device such as LCD.

The docking station 1 may further contain the PMU 50. The PMU 50 may receive commands from the control unit 40 to power and/or charge the cell phone 2 via the communication interface 20 as described below. In this case, the docking station 1 can not only display an enlarged image but also function as an on-line charger for the cell phone 2.

The PMU 50 is capable of providing power to the docking station 1 and/or the cell phone 2, and may also manage charging of the docking station 1 and cell phone batteries. The main function of the PMU 50 is intelligent power management for minimized power consumption, an important application in mobile devices. Docking station and cell phone power can be sourced from an internal battery or from an external AC power source. When the product is running on external AC power, the PMU 50 may convert the native AC voltage and frequency to the appropriate internal AC and DC levels and/or frequencies. Each module in the docking station 1 may be designed to provide low power operation options. The PMU 50 may manage each module's power mode. The lamp in the projection unit 30 consumes significant power resources and hence its luminous output may be configurable by the PMU 50 for power saving. The microdisplay device in the projection unit 30 likewise consumes significant power resources and may be configurable by the PMU 50 for power mitigation. For control and communications with batteries and power management hardware in the cell phone 2, the PMU 50 may provide serial and UART master and slave capabilities. Some devices may require this communication and control to be embedded in processor communications, and in this case the PMU 50 may interface with the communications interface 20 for such communication.

The PMU 50 may be configured to have a DC input end for receiving DC power from a battery 6 and an AC input end for receiving AC power from an external electric outlet 54. Based on control from the control unit 40, the PMU 50 may selectively receive external power from a power supply and the battery 6. The battery 6 may be a dedicated spare DC power supply for the docking station 1. Alternatively, the battery 6 may be a spare battery for the cell phone 2. Referring to FIG. 1A, the battery 6 is held in the battery bay 7, which is formed on the surface of the housing 3. Similar to the docking bay 8, the position and the shape of the battery bay 7 may be designed as appropriate to the particular application.

The battery bay 7 may be provided with a charging connector or battery port that may be connected with a complementary charging connector in the battery 6 when the battery 6 is placed in position. The battery port of the battery bay 7 serves as one of the output terminals of the PMU 50 and is configured to output the desired charging voltage and/or current to the battery 6. According to an embodiment, the docking station 1 of the invention may serve as a charger for the cell phone 2 as well as the battery 6. It can charge the cell phone 2 and the battery 6 while displaying the information from the cell phone 2.

As another embodiment, the battery bay 7 may further include a powering connector for outputting the power from the battery 6 into the PMU 50 such that the docking station 1 may operate without using an external electric supply. Alternatively, the battery inside the cell phone may also be used as a power supply for the docking station 1. According to this alternative embodiment, the docking station 1 may be operable to project multimedia information in mobile conditions. It will be appreciated by one of skill in the art that the battery 6 and the battery bay 7 are also optional.

The PMU 50 may be implemented by a power transforming circuit to transform the received power into a plurality of levels of power for powering the projection unit 30, charging the battery 6, powering and/or charging the cell phone 2. The communication interface 20 may first receive power from the PMU 50 and then power and/or charge the cell phone 2 in response to the control of the control unit 40.

In a particular embodiment, the levels of output power may be adjustable under the control of the control unit 40. This is useful for power savings during operation. For example, when the cell phone 2 is transferring its information to the docking station 1, the screen of the cell phone 2 may be in the state of OFF or set at a lower luminance level. In this case, the control unit 40 may instruct the PMU 50 to output a lower level of power for the display of the cell phone 2. According to change of the ambient brightness and the display time of a projected image, the PMU 50 may be controlled by the control unit 40 to supply a lower power or even stop the power supply to the lamp of the projection unit 30 in order to reduce power consumption.

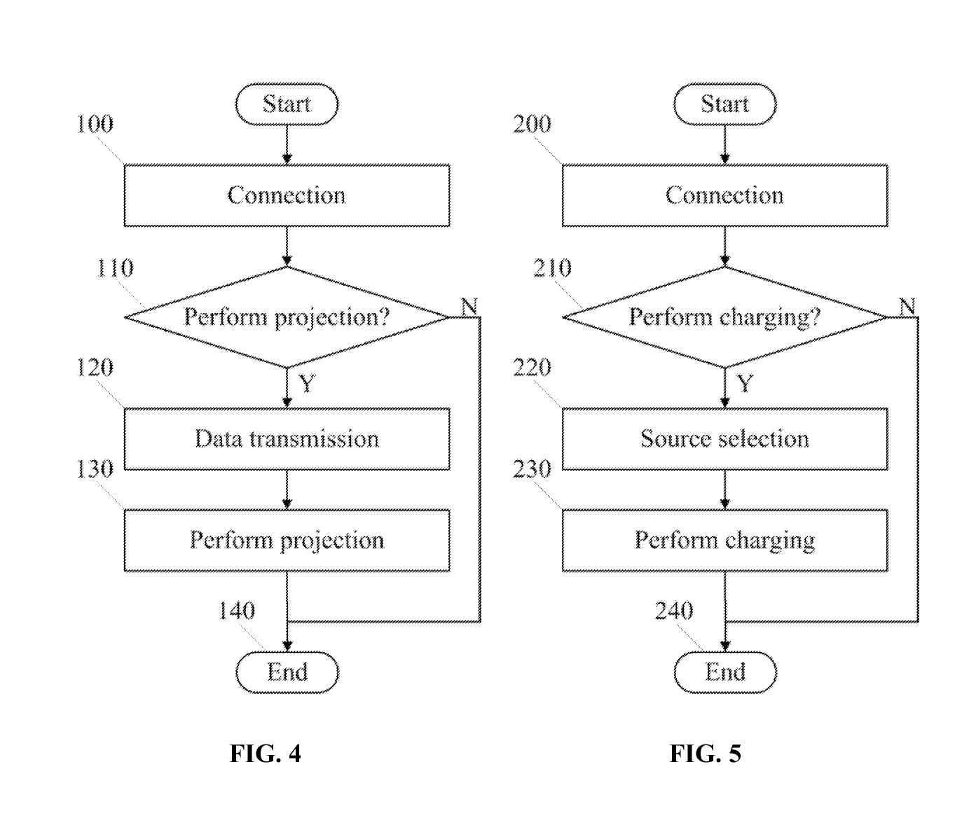

FIG. 4 is a simplified flowchart illustrating operation of the docking station in a projection application according to an embodiment of the present invention. At step 100, a portable device, for example the cell phone 2, is connected to the docking port 10 of the docking station 1. Such an operation may be accomplished, for example, by putting the cell phone 2 into the docking bay 4 to make the input/output port of the cell phone connect with the electrical contacts in the docking port 10. Alternatively, such an operation may be accomplished by operating the cell phone 2 to send a wireless communication signal to the docking station 1 and receiving a signal from the docking station 1 indicating successful connection.

At step 110, a determination is made of whether the docking station 1 is required to perform projection. Such a determination may be made by the control unit 40 according to a user's input from the user interface 74. If the determination is affirmative, the process proceeds to step 120, otherwise it ends at step 140.

At step 120, the data from the cell phone 2 is transmitted into the front end 22 of the communication interface 20. The data is voltage-translated and converted in accordance with the internal standard of the docking station 1, and transmitted through the back end 24 of the communication interface 20 to the projection unit 30 via the video bus 62. The control unit 40 may also adjust the parameters of data transmission. Then the process proceeds to step 130.

At step 130, the docking station 1 performs image projection through the projection unit 30. Additionally, if the data is recognized to include audio contents, the docking station may both project an image through the projection unit 30 and perform audio output through the audio unit 72. The video and audio signals may have been synchronized in the communication interface 20 as discussed above. After step 130, the projection process is complete, and the process ends at step 140. After the projection process is complete, the cell phone 2 may be disconnected from the docking port 10.

FIG. 5 is a simplified flowchart illustrating operation of the docking station in a charging application according to an embodiment of the present invention. At step 200, a portable device, for example the cell phone 2, is connected to the docking port 10 of the docking station 1. Such an operation may be accomplished, for example, by putting the cell phone 2 into the docking bay 4 to make the input/output port connect with the electrical contacts in the docking port 10. After a successful connection, a signal is preferably sent to the control unit 40 for notification.

At step 210, a determination is made of whether the cell phone 2 requires charging from the docking station 1. Such a determination may be made by the control unit 40 according to a user's input from the user interface 74. Alternatively, if a battery monitor or a sensor provided either in the cell phone 2 or the docking station 1 detects that the battery of the cell phone 2 requires charging, the control unit 40 may receive a signal from it and make a positive determination automatically. If the determination in step 210 is affirmative, the charging process proceeds to step 220, otherwise it ends at step 240.

At step 220, the control unit 40 may determine the source of power for charging the battery of the cell phone 2. The determination may be based on a predetermined and stored configuration parameter, or depend on user's input. For example, the control unit 40 may determine to charge the cell phone 2 with power from an electric outlet 54 if the PMU 50 of the docking station 1 is in connection with an electric outlet 54; or with power from the battery 6 in the battery bay 7 if the PMU 50 is not in connection with an electric outlet.

At step 230, the cell phone 2 is charged with power from the source selected at step 220. If the charging source is an electric outlet 54, the battery 6 may also be charged as required. After the charging process completes, the charging process ends at step 240. The cell phone 2 may be disconnected from the docking station 1 at this time.

In addition to the separate projection and charging processes illustrated in FIG. 4 and FIG. 5, respectively, the projection and charging processes may be performed in parallel as appropriate after the cell phone 2 is connected.

It should be noted that although the invention has been described with respect to several functional modules, these modules are not to be naturally interpreted to be implemented as separate components. For example, these modules may be parts of an integrated circuit or a chip. Although the invention has been specifically described with reference to the drawings, the invention is not limited by the same, but limited by the appended claims and equivalents.

What is claimed is:

1. A projection docking station comprising:
a docking port configured to communicate with a portable device;
a projection unit configured to perform a projection process for an image;
a communication interface configured to provide communications between the docking port and the projection unit; and
a control unit configured to communicate with the communication interface and the projection unit, wherein the control unit is configured to control:
a communication flow between the communication interface and the docking port;
a communication flow between the communication interface and the projection unit; and
the projection process.

2. The projection docking station of claim 1 wherein the docking port comprises a wireless transceiver configured to provide wireless communication with the portable device.

3. The projection docking station of claim 1 wherein the projection unit, the communication interface, and the control unit are enclosed in a housing.

4. The projection docking station of claim 3 further comprising a docking bay provided on the housing and shaped to receive the portable device, wherein the docking port is provided in the docking bay.

5. The projection docking station of claim 1 wherein the communication flow between the communication interface and the projection unit comprises transmission of image data from the communication interface to the projection unit.

6. The projection docking station of claim 1 wherein the communication flow between the communication interface and the docking port comprises transmission of video and audio data from the docking port to the communication interface.

7. The projection docking station of claim 6 wherein the communication flow between the communication interface and the docking port further comprises power transmission from the communication interface to the docking port.

8. The projection docking station of claim 1 further comprising an audio unit configured to receive one or more control signals from the control unit, wherein the audio unit is configured to receive and reproduce audio data received from the communication interface.

9. The projection docking station of claim 1 further comprising a user interface coupled to the control unit and configured to receive one or more user inputs.

10. The projection docking station of claim 1 further comprising a power management unit configured to receive external power and output predetermined levels of power to the projection unit, wherein the control unit is further configured to communicate with the power management unit and provide control signals to the power management unit.

11. The projection docking station of claim 10 wherein the power management unit is further configured to output power to the docking port through the communication interface.

12. The projection docking station of claim 10 wherein the predetermined levels of power are adjustable.

13. The projection docking station of claim 10 further comprising a battery bay configured to receive a battery and including a battery port configured to provide electrical connectivity to the charge the battery, wherein the battery port is configured to receive power from the power management unit.

14. The projection docking station of claim 13 further comprising a power connector provided in the battery bay and configured to receive power from the battery and transfer the power to the power management unit.

15. A method of operating a projection docking station, the method comprising:
coupling a portable device to a docking port of the projection docking station;
determining if a projection process is to be performed using the docking station;
transmitting data from the portable device to a communication interface of the docking station; and
projecting an image from a projection unit of the docking station.

16. The method of claim 15 wherein coupling the portable device to the docking port comprising placing the portable device in a docking bay of the docking port.

17. The method of claim 16 wherein coupling the portable device to the docking port comprising connecting the portable device to the docking port using a connector cable.

18. The method of claim 15 wherein the docking station further comprises an audio unit configured to receive and reproduce audio data received from the communication interface.

19. The method of claim 18 further comprising transmitting an audio signal from the audio unit.

20. A method of operating a projection docking station, the method comprising:
coupling a portable device to a docking port of the docking station;
determining that a charging process is to be performed on the portable device;
determining a power source to be used for the charging process; and
charging the portable device using power from the power source.

21. The method of claim 20 wherein the power source is at least one of a battery connected to the docking station or an electric outlet.
